(19) United States
(12) Patent Application Publication
(10) Pub. No.: US 2025/0194078 A1
(43) Pub. Date: Jun. 12, 2025

(54) SEMICONDUCTOR DEVICES HAVING CHANNEL STRUCTURES

(71) Applicant: Samsung Electronics Co., Ltd., Suwon-si (KR)

(72) Inventors: Heonjun Ha, Suwon-si (KR); Hyeontae Kim, Suwon-si (KR); Julpin Park, Suwon-si (KR)

(21) Appl. No.: 18/737,964

(22) Filed: Jun. 8, 2024

(30) Foreign Application Priority Data
Dec. 7, 2023 (KR) 10-2023-0176377

(51) Int. Cl. H10B 12/00; H01L 23/00; H01L 25/00; H01L 25/065; H01L 25/18; H10B 80/00

(52) U.S. Cl. CPC H10B 12/33; H01L 24/08; H01L 24/80; H01L 25/0657; H01L 25/18; H01L 25/50; H10B 12/036; H10B 12/05; H10B 80/00; H01L 2224/08145; H01L 2224/80895; H01L 2224/80896; H01L 2924/1431; H01L 2924/1436

(57) ABSTRACT

A semiconductor device includes an information storage structure on a substrate;

a landing pad on the information storage structure; a channel structure including a horizontal portion contacting an upper surface of the landing pad, and a vertical channel portion extending from one end of the horizontal portion in an upward direction; a gate electrode disposed on the horizontal portion; and a bit line contacting an upper surface of the vertical channel portion and electrically connected to the channel structure. A lower surface of the horizontal portion is located on a level lower than an upper end of the landing pad. A side surface of the vertical channel portion is partially in contact with the landing pad.

### CROSS-REFERENCE TO RELATED APPLICATION(S)

This application claims benefit of priority under 35 U.S.C. § 119 to Korean Patent Application No. 10-2023-0176377, filed on Dec. 7, 2023, in the Korean Intellectual Property Office, the contents of which is incorporated herein by reference in its entirety.

### BACKGROUND

The present inventive concept relates to a semiconductor device including a channel structure.

As the demand for high performance, speed and/or multi-functionality of a semiconductor device increases, a degree of integration of the semiconductor device is increasing. In manufacturing a fine patterned semiconductor device in response to the trend of a high degree of integration of the semiconductor device, it is required to implement patterns having a fine width or a fine spacing distance.

### SUMMARY

An aspect of the present inventive concept is to provide a semiconductor device including a channel structure disposed on an information storage structure.

According to an aspect of the present inventive concept, a semiconductor device includes an information storage structure on a substrate; a landing pad on the information storage structure; a channel structure including a horizontal portion contacting an upper surface of the landing pad, and a vertical channel portion extending from one end of the horizontal portion in an upward direction; a gate electrode disposed on the horizontal portion; and a bit line contacting an upper surface of the vertical channel portion and electrically connected to the channel structure. A lower surface of the horizontal portion is located on a lower level than an upper end of the landing pad. A side surface of the vertical channel portion is partially in contact with the landing pad.

According to an aspect of the present inventive concept, a semiconductor device includes a cell array structure; and a peripheral circuit structure vertically overlapping the cell array structure and including a circuit element. The cell array structure includes an information storage structure; a landing pad on the information storage structure; a channel structure including a horizontal portion contacting an upper surface of the landing pad, and a vertical channel portion extending from one end of the horizontal portion in an upward direction; a gate electrode disposed on the horizontal portion; a first insulating pattern contacting the vertical channel portion; a second insulating pattern covering the gate electrode; and a bit line contacting an upper surface of the vertical channel portion and electrically connected to the channel structure. The upper surface of the vertical channel portion is disposed on a higher level than an upper surface of the first insulating pattern, and a lower surface of the horizontal portion is disposed on a lower level than a lower surface of the first insulating pattern.

According to an aspect of the present inventive concept, a semiconductor device includes an information storage structure on a substrate; a landing pad on the information storage structure; a channel structure including a horizontal portion contacting an upper surface of the landing pad, and a vertical channel portion extending from one end of the horizontal portion in an upward direction; a gate electrode disposed on the horizontal portion; a dielectric structure between the channel structure and the gate electrode; a first insulating pattern contacting the vertical channel portion; a second insulating pattern covering the gate electrode and the dielectric structure; a bit line contacting an upper surface of the vertical channel portion and electrically connected to the channel structure; a first bonding layer on the bit line; and a peripheral circuit structure including a second bonding layer bonded to the first bonding layer and a circuit element on the second bonding layer. A side surface of a lower portion of the vertical channel portion is in contact with the landing pad, and a side surface of an upper portion of the vertical channel portion is in contact with the bit line.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an example embodiment.

FIG. 2 is a vertical cross-sectional view taken along line I-I′ of the semiconductor device illustrated in FIG. 1.

FIG. 3 is a vertical cross-sectional view taken along line II-II′ of the semiconductor device illustrated in FIG. 1.

FIG. 4 is a partially enlarged view of the semiconductor device illustrated in FIG. 2.

FIGS. 5 to 10 are vertical cross-sectional views of semiconductor devices according to example embodiments.

FIGS. 11 and 12 are flow charts illustrating a method of manufacturing a semiconductor device according to an example embodiment.

FIGS. 13A to 13K are vertical cross-sectional views illustrated according to a process sequence for illustrating a method of manufacturing a semiconductor device according to an example embodiment.

FIG. 14 is a vertical cross-sectional view of a semiconductor device according to an example embodiment.

FIG. 15 is a partially enlarged view of the semiconductor device illustrated in FIG. 14.

FIGS. 16 and 17 are vertical cross-sectional views of semiconductor devices according to example embodiments.

FIGS. 18A to 18C are vertical cross-sectional views illustrated according to a process sequence for illustrating a method of manufacturing a semiconductor device according to an example embodiment.

FIG. 19 is a vertical cross-sectional view of a semiconductor device according to an example embodiment.

FIG. 20 is a flow chart illustrating a method of manufacturing a semiconductor device according to an example embodiment.

FIGS. 21A to 21D are vertical cross-sectional views illustrated according to a process sequence for illustrating a method of manufacturing a semiconductor device according to an example embodiment.

### DETAILED DESCRIPTION

Hereinafter, preferred embodiments of the present inventive concept will be described with reference to the attached drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

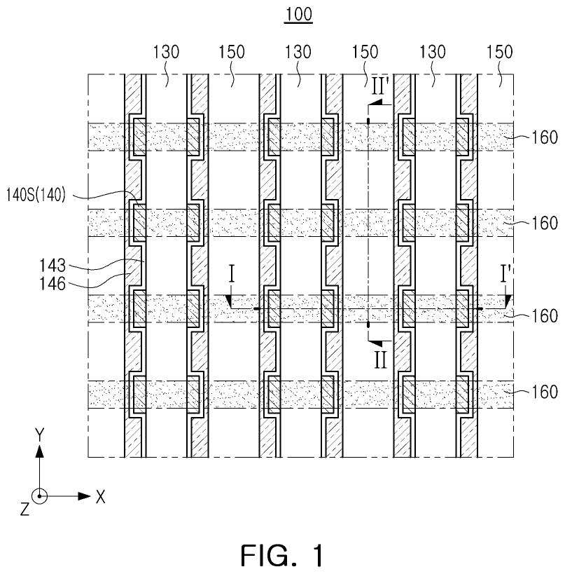

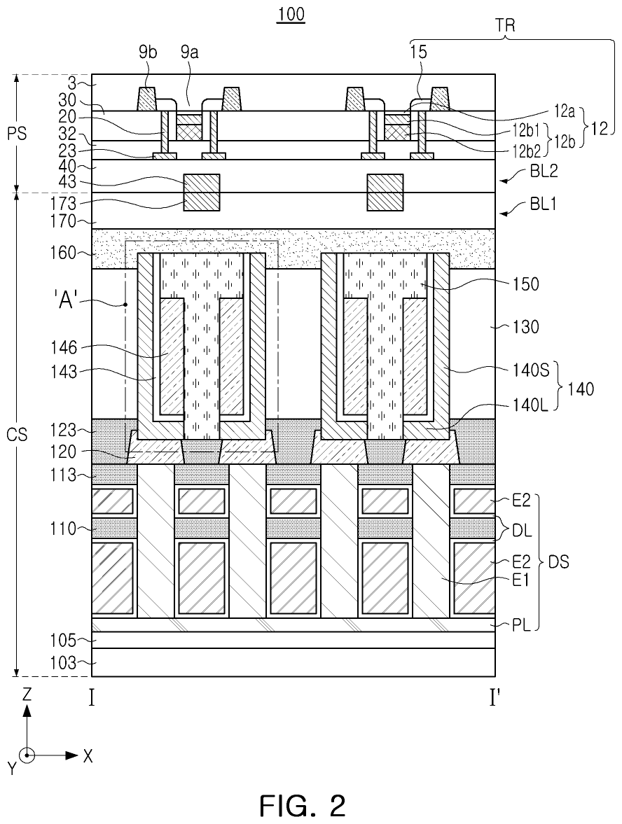

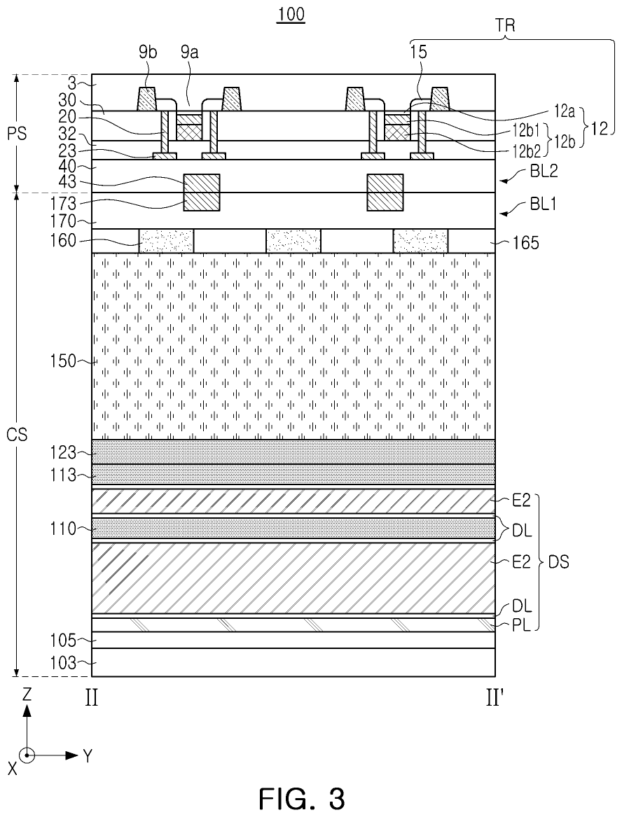

FIG. 1 is a plan view of a semiconductor device according to an example embodiment. FIG. 2 is a vertical cross-sectional view taken along line I-I′ of the semiconductor device illustrated in FIG. 1. FIG. 3 is a vertical cross-sectional view taken along line II-II′ of the semiconductor device illustrated in FIG. 1.

Referring to FIGS. 1 to 3, a semiconductor device 100 according to an embodiment may include a cell array structure CS and a peripheral circuit structure PS on the cell array structure CS. The cell array structure CS may include an information storage structure DS disposed on a substrate 103, a landing pad 120, a channel structure 140, and a bit line 160. Hereinafter, the X-direction and Y-direction may be parallel to the upper surface of the substrate 103 and may be defined as horizontal directions, and the Z-direction may be perpendicular to the upper surface of the substrate 103 and may be defined as a vertical direction (e.g., an upward direction or downward direction). The X-direction, the Y-direction, and the Z-direction may be orthogonal to one another.

The substrate 103 may include a semiconductor material, such as a group IV semiconductor, a group III-V compound semiconductor, or a group II-VI compound semiconductor. For example, the group IV semiconductor may include silicon, germanium, or silicon-germanium. The substrate 103 may include a silicon substrate, a silicon-on-insulator (SOI) substrate, a germanium substrate, a germanium-on-insulator (GOI) substrate, a silicon-germanium substrate, or a substrate including an epitaxial layer.

The information storage structure DS may be disposed on the substrate 103. In an embodiment, the semiconductor device 100 may further include an insulating layer 105 disposed between the substrate 103 and the information storage structure DS. The insulating layer 105 may electrically insulate the substrate 103 from the peripheral circuit structure PS. The insulating layer 105 may contact an upper surface of the substrate 103 and a lower surface of the information storage structure DS, although embodiments are not limited thereto.

The information storage structure DS may include a plate electrode PL, first electrodes E1, a second electrode E2 on the first electrodes E1, and a dielectric layer DL between each of the first electrodes E1 and the second electrode E2.

The plate electrode PL may be disposed on the insulating layer 105, and may cover the insulating layer 105. The first electrodes E1 may be disposed on the plate electrode PL, and may extend in a vertical direction (e.g., Z-direction). The first electrodes E1 may be spaced apart from each other in a horizontal direction (e.g., X-direction). The plate electrode PL and the first electrodes E1 may be formed of or include at least one of TiN, TiAlN, TiSiN, TaN, TaAlN, TaSiN, or WN.

The cell array structure CS may further include a lower support layer 110 and an upper support layer 113, arranged between the first electrodes E1. The lower support layer 110 and the upper support layer 113 may be in contact with side surfaces of the first electrodes E1, and may support the first electrodes E1. The upper support layer 113 may be disposed on the lower support layer 110. For example, an upper surface of the upper support layer 113 may be coplanar with an upper surface of the first electrodes E1. In an embodiment, the lower support layer 110 may be omitted. The lower support layer 110 and the upper support layer 113 may include an insulating material, and may include, for example, silicon oxide, silicon nitride, silicon oxynitride, or a combination thereof. In an embodiment, the lower support layer 110 and the upper support layer 113 may include silicon nitride.

The dielectric layer DL may cover the first electrodes E1, the lower support layer 110, and the upper support layer 113. For example, the dielectric layer DL may be formed conformally along surfaces of the plate electrode PL, the first electrodes E1, the lower support layer 110, and the upper support layer 113. The dielectric layer DL may cover upper and lower surfaces of the lower support layer 110 and a lower surface of the upper support layer 113. For example, the dielectric layer DL may contact upper and lower surfaces of the lower support layer 110 and the lower surface of the upper support layer 113. In addition, the dielectric layer DL may contact side surfaces of the first electrodes E1.

In an embodiment, the information storage structure DS may be a capacitor storing information in a DRAM. For example, the dielectric layer DL of the information storage structure DS may be a capacitor dielectric layer of the DRAM, and the dielectric layer DL may be formed of or include a high-κ dielectric, silicon oxide, silicon nitride, silicon oxynitride, or a combination thereof.

In another example, the information storage structure DS may be a structure storing information of a memory, different from the DRAM. For example, the information storage structure DS may be a capacitor of a ferroelectric memory (FeRAM). For example, the dielectric layer DL may be a ferroelectric layer capable of recording data using a polarization state. In another example, the dielectric layer DL may include a lower dielectric layer and a ferroelectric layer on the lower dielectric layer. In this case, the lower dielectric layer may be formed of or include at least one of silicon oxide, silicon oxynitride, silicon nitride, or a high-κ dielectric.

In an embodiment, when the dielectric layers DL include an information storage layer, the information storage structure DS may be omitted.

The second electrode E2 may cover the dielectric layer DL, and may fill a space between the first electrodes E1. The second electrode E2 may not cover the upper surface of the first electrodes E1, and an upper surface of the second electrode E2 may be located on a level lower than the upper surface of the first electrodes E1. The second electrode E2 may include a semiconductor material, and may include, for example, silicon germanium (SiGe) containing an impurity. In an embodiment, the first electrode E1 may be referred to as a lower electrode, and the plate electrode PL and the second electrode E2 may be referred to as an upper electrode.

The landing pad 120 may be disposed on the information storage structure DS. For example, each of the landing pads 120 may be in contact with and electrically connected to an upper surface of a first electrode E1 corresponding thereto. In an embodiment, a horizontal width of a lower surface of the landing pad 120 may be greater than a horizontal width of the upper surface of the first electrode E1. In an embodiment, a horizontal width of the landing pad 120 may become smaller in an upward direction (e.g., Z-direction). For example, the horizontal width of the landing pad 120 may become smaller toward the channel structure 140. In example embodiments, a horizontal width of the lower surface of the landing pad 120 and a horizontal width of an upper surface of the landing pad 120 may be greater than the horizontal width of the upper surface of the first electrode E1.

The landing pad 120 may be formed of or include metal nitride, metal, or a combination thereof. The metal nitride may include at least one of TiN, TaN, WN, TiSiN, TaSiN, or RuTiN, and the metal may include a metal material such as W, Mo, or the like.

The cell array structure CS may further include a pad insulating layer 123 covering the landing pads 120. The pad insulating layer 123 may contact side and upper surfaces of the landing pads 120. A lower surface of the pad insulating layer 123 may be in contact with the upper surface of the upper support layer 113, and an upper surface of the pad insulating layer 123 may be located on a level higher than a level of the upper surfaces of the landing pads 120. The lower surface of the pad insulating layer 123 may be coplanar with lower surfaces of the landing pads 120. The pad insulating layer 123 may include silicon oxide, silicon nitride, silicon oxynitride, a low-κ dielectric, or a combination thereof, and may include, for example, silicon nitride.

The cell array structure CS may be disposed on the landing pads 120, and may further include first insulating patterns 130 contacting the pad insulating layer 123. The first insulating patterns 130 may extend lengthwise in the Y-direction, and may be spaced apart from each other in the X-direction. The first insulating patterns 130 may include silicon oxide, silicon nitride, silicon oxynitride, or a combination thereof. The first insulating patterns 130 may be formed as a single layer or multiple layers.

The channel structure 140 may be disposed on the landing pad 120. The channel structure 140 may include a horizontal portion 140L contacting and electrically connected to the bit line 160, and a vertical channel portion 140S extending from one end of the horizontal portion 140L in the X-direction in an upward direction (e.g., Z-direction). A lower surface of the horizontal portion 140L may be in contact with the landing pad 120, and the horizontal portion 140L may be electrically connected to the landing pad 120. In an embodiment, the vertical channel portion 140S may extend in a direction, oblique to the vertical direction (Z-direction), but the present inventive concept is not limited thereto. Channel structures 140 may be spaced apart from each other in the X and Y-directions. A height of each of the channel structures 140 may be greater than a height of each of the first insulating patterns 130. For example, upper surfaces of the channel structures 140 may be at a higher vertical level than upper surfaces of the first insulating patterns 130.

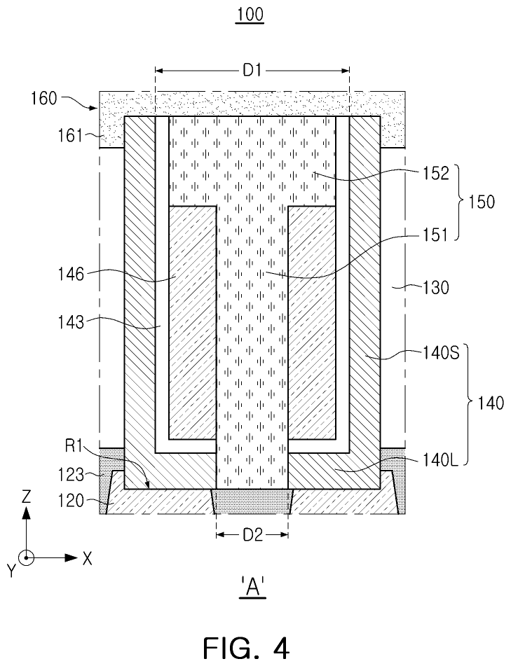

FIG. 4 is a partially enlarged view of the semiconductor device illustrated in FIG. 2. FIG. 4 may correspond to portion A illustrated in FIG. 2.

Referring further to FIG. 4, the lower surface of the horizontal portion 140L and a side surface of the vertical channel portion 140S may be in contact with the landing pad 120. For example, the lower surface of the horizontal portion 140L may be located on a level lower than an upper surface of the landing pad 120. The landing pad 120 may include a recess region R1 formed on an upper surface of the landing pad 120, and the recess region R1 may be in contact with the horizontal portion 140L and the vertical channel portion 140S. Additionally, the side surface of the vertical channel portion 140S may partially contact the pad insulating layer 123.

As illustrated in FIG. 4, since two surfaces of the channel structure 140 according to an embodiment may be in contact with the landing pad 120, a contact area between the channel structure 140 and the landing pad 120 may increase, and contact resistance may be lowered. Therefore, electrical characteristics of the semiconductor device 100 may be improved.

A horizontal distance between channel structures 140 may not be constant. For example, first and second channel structures 140, among the channel structures 140, may be spaced apart from each other, with a second insulating pattern 150 therebetween. A distance D1 between the first channel structure 140 and the second channel structure 140 on a first vertical level, equal to a lower surface of the bit line 160, may be greater than a distance D2 between the first channel structure 140 and the second channel structure 140 on a second vertical level, equal to an upper surface of the landing pad 120.

The channel structure 140 may be formed of a semiconductor material such as silicon or the like. The channel structure 140 may be formed of single crystal silicon or polysilicon. The channel structure 140 is not limited to the semiconductor material such as silicon or the like, and may be formed of other semiconductor materials that may be used as a channel region of a transistor. For example, the channel structure 140 may include an oxide semiconductor layer or a two-dimensional material layer that may be used as the channel region of the transistor.

The oxide semiconductor layer may include indium gallium zinc oxide (IGZO), but an embodiment is not limited thereto. For example, the oxide semiconductor layer may include at least one of indium tungsten oxide (IWO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The two-dimensional material layer may include at least one of a transition metal dichalcogenide (TMD) material layer, a black phosphorous material layer, and a hexagonal boron-nitride (hBN) material layer, which may have semiconductor properties. For example, the two-dimensional material layer may be BiOSe, Crl, WSe₂, MoS₂, TaS, WS, SnSe, ReS, β-SnTe, MnO, AsS, P (black), InSe, h-BN, GaSe, GaN, SrTiO, MXene, or Janus 2D materials, which may form a two-dimensional material.

The cell array structure CS may further include gate electrodes 146 disposed on the channel structures 140, and dielectric structures 143 disposed between the gate electrodes 146 and the channel structures 140.

When viewed in plan view, the gate electrodes 146 may intersect the bit lines 160. For example, the gate electrodes 146 may extend lengthwise in the Y-direction along a side surface of the first insulating patterns 130, and may be spaced apart from each other in the X-direction. The gate electrode 146 may overlap the horizontal portion 140L of the channel structure 140 in the vertical direction. An upper end of the gate electrode 146 may be located on a level lower than the upper surface of the first insulating pattern 130. At least one of the gate electrodes 146 may be a cell gate electrode or a word line.

The dielectric structures 143 may be disposed between the gate electrode 146 and the vertical channel portion 140S, and between the gate electrode 146 and the horizontal portion 140L. The dielectric structures 143 may contact the gate electrodes 146, the vertical channel portions 140S, the horizontal portions 140L, and the second insulating patterns 150. Upper surfaces of the dielectric structures 143 may contact the bit lines 160. In an embodiment, a portion of the dielectric structure 143 may cover the upper surface of the first insulating pattern 130, but the present inventive concept is not limited thereto. In an example, each of the dielectric structures 143 may be a tunnel dielectric layer

not including an information storage layer. For example, each of the dielectric structures 143 may include at least one of silicon oxide or a high-κ dielectric. The high-κ dielectric may include metal oxide or metal oxynitride. For example, the high-κ dielectric may be made of HfO₂, HfSiO, HfSiON, HfTaO, HfTiO, HfZrO, ZrO₂, Al₂O₃, or a combination thereof, but the present inventive concept is not limited thereto. Each of the dielectric structures 143 may be formed as a single layer or multiple layers of the above-described materials.

In another example, each of the dielectric structures 143 may include an information storage layer and a dielectric layer. For example, each of the dielectric structures 143 may have polarization characteristics depending on an electric field, and may include a ferroelectric layer that may have remnant polarization due to a dipole even in the absence of an external electric field. Data may be recorded using a polarization state in the ferroelectric layer. Therefore, each of the dielectric structures 143 may include a ferroelectric layer, which may be referred to as an information storage layer. The ferroelectric layer, which may be the information storage layer, may include an Hf-based compound, a Zr-based compound, and/or an Hf-Zr-based compound. For example, the Hf-based compound may include a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with an impurity, such as at least one of C, Si, Mg, Al, Y, N, Ge, Sn, Gd, La, Sc, or Sr. For example, the ferroelectric layer, which may be the information storage layer, may be a material doped with at least one of an impurity, C, Si, Mg, Al, Y, N, Ge, Sn, Gd, La, Sc, or Sr, in addition to at least one of HfO₂, ZrO₂, or HZrO.

In the dielectric structures 143, the information storage layer is not limited to the above-described material types, and may include a material capable of storing information.

The cell array structure CS may further include second insulating patterns 150 covering the gate electrodes 146. The second insulating patterns 150 may contact the gate electrodes 146. The second insulating pattern 150 may include a lower portion 151 and an upper portion 152. The lower portion 151 of the second insulating pattern 150 may extend vertically between the horizontal portions 140L of the channel structures 140 and between the gate electrodes 146. A lower surface of the lower portion of the second insulating pattern 150 may be coplanar with lower surfaces of the horizontal portions 140L. A horizontal width of the upper portion 152 of the second insulating pattern 150 may be greater than a horizontal width of the lower portion 151. An upper surface of the upper portion 152 of the second insulating pattern 150 may be coplanar with upper surfaces of the vertical channel portions 140S. In an embodiment, a height of the second insulating pattern 150 may be equal to a height of the channel structure 140, and may be greater than a height of the first insulating pattern 130. The second insulating patterns 150 may extend lengthwise in the Y-direction, and may be spaced apart from each other in the X-direction. The second insulating patterns 150 may be alternately arranged in the X-direction with the first insulating patterns 130.

The second insulating patterns 150 may include silicon oxide, silicon nitride, silicon oxynitride, or a combination thereof. The second insulating patterns 150 may be formed as a single layer or multiple layers.

The bit line 160 may be disposed on the channel structure 140, and may intersect the gate electrode 146. The bit lines 160 may extend lengthwise in the X-direction, and may be spaced apart from each other in the Y-direction. The bit line 160 may be electrically connected to the landing pad 120 through the channel structure 140. The bit line 160 may include a metal layer and a barrier layer covering side and lower surfaces of the metal layer. The barrier layer may include at least one of TiN, TaN, WN, TiSiN, TaSiN, or RuTiN, and the metal layer may include a metal material such as W, Mo, or the like.

Upper and side surfaces of the vertical channel portion 140S may be in contact with the bit line 160. For example, the bit line 160 may include protrusions 161 contacting the second insulating pattern 150 and extending from the lower surface of the bit line 160 in a downward direction. Lower ends of the protrusions 161 may be located on a level lower than the upper surface of the vertical channel portion 140S, and may be in contact with the side surface of the vertical channel portion 140S. Lower surfaces of the protrusions 161 may contact upper surfaces of the first insulating patterns 130.

As illustrated in FIG. 4, since two surfaces of the channel structure 140 according to an embodiment may be in contact with the bit line 160, a contact area between the channel structure 140 and the bit line 160 may increase, and contact resistance may be lowered. Therefore, electrical characteristics of the semiconductor device 100 may be improved.

The cell array structure CS may further include a bit line insulating layer 165 disposed between the bit lines 160. The bit line insulating layer 165 may be disposed on the same level as the bit lines 160, and may electrically insulate the bit lines 160 from each other. For example, upper and lower surfaces of the bit line insulating layer 165 may be coplanar with upper and lower surfaces, respectively, of the bit lines 160. The bit line insulating layer 165 may include silicon oxide, silicon nitride, silicon oxynitride, or a combination thereof.

Although not illustrated, in some embodiments, the cell array structure CS may further include shield patterns extending in the X-direction and spaced apart from each other in the Y-direction. The shield patterns may be arranged alternately with the bit lines 160 in the Y-direction. A lower surface of a shield pattern may be located on a level lower than the lower surface of the bit line 160, and an upper surface of the shield pattern may be located on a level lower than the upper surface of the bit line 160. The shield patterns may reduce capacitance between bit lines 160.

The shield pattern may include doped polysilicon, metal, conductive metal nitride, a metal-semiconductor compound, a metal compound, conductive metal oxide, graphene, a carbon nanotube, or a combination thereof.

The cell array structure CS may further include a bonding layer BL1 disposed on the bit line 160 and the bit line insulating layer 165. The bonding layer BL1 may include an upper insulating layer 170 and bonding pads 173. Bonding pads 173 may be disposed in the upper insulating layer 170. For example, upper surfaces of the bonding pads 173 may be coplanar with an upper surface of the upper insulating layer 170. The upper insulating layer 170 may contact lower and side surfaces of the bonding pads 173. The bit line 160 may be electrically connected to at least one of the bonding pads 173. In an embodiment, an interconnection layer may be further disposed in the upper insulating layer 170 to electrically connect the bonding pads 173 and the bit line 160.

The peripheral circuit structure PS may be disposed on the cell array structure CS. The peripheral circuit structure PS may include a substrate 3, a circuit element TR, a peripheral plug 20, a peripheral interconnection 23, a first peripheral insulating layer 30, and a second peripheral insulating layer 32.

The substrate 3 may include a semiconductor material, such as a group IV semiconductor, a group III-V compound semiconductor, or a group II-VI compound semiconductor. For example, a group IV semiconductor may include silicon, germanium, or silicon-germanium. The substrate 3 may include a silicon substrate, a silicon-on-insulator (SOI) substrate, a germanium substrate, a germanium-on-insulator (GOI) substrate, a silicon-germanium substrate, or a substrate including an epitaxial layer.

The circuit element TR may include a word line driver, a sense amplifier, row and column decoders, and control circuits. The circuit element TR may include a peripheral transistor. For example, the peripheral transistor may include a gate structure 12 disposed on a peripheral active region 9a defined by an element isolation region 9b in the substrate 3, and peripheral source/drain regions 15 disposed in the peripheral active region 9a on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 below the first conductive layer 12b1.

The peripheral plug 20 may be connected to a peripheral source/drain region 15, and may extend vertically, and the peripheral interconnection 23 may be disposed below the peripheral plug 20. The peripheral interconnection 23 may contact the peripheral plug 20. The peripheral interconnection 23 may be electrically connected to the circuit element TR through the peripheral plug 20. The first peripheral insulating layer 30 may surround side surfaces of the peripheral gate electrode 12b and the peripheral plug 20. The second peripheral insulating layer 32 may be disposed below the first peripheral insulating layer 30, and may surround the peripheral plug 20 and the peripheral interconnection 23. A lower surface of the second peripheral insulating layer 32 may be coplanar with a lower surface of the peripheral interconnection 23.

In an embodiment, the peripheral plug 20 and the peripheral interconnection 23 may include a metal layer and a barrier layer covering side and lower surfaces of the metal layer, respectively. The barrier layer may include at least one of TiN, TaN, WN, TiSiN, TaSiN, or RuTiN, and the metal layer may include a metal material such as W, Mo, or the like. The first peripheral insulating layer 30 and the second peripheral insulating layer 32 may include silicon oxide, silicon nitride, silicon oxynitride, a low-κ dielectric, or a combination thereof.

The peripheral circuit structure PS may further include a bonding layer BL2 disposed below the peripheral interconnection 23. The bonding layer BL2 may include a lower insulating layer 40 and a bonding pad 43. Bonding pads 43 may be disposed in the lower insulating layer 40. For example, a lower surface of the bonding pads 43 may be coplanar with a lower surface of the lower insulating layer 40. The peripheral interconnection 23 may be electrically connected to at least one of the bonding pads 43. In an embodiment, an interconnection layer may be further disposed in the lower insulating layer 40 to electrically connect the bonding pads 43 and the peripheral interconnection 23.

The peripheral circuit structure PS may be bonded to the cell array structure CS, and may be electrically connected to the cell array structure CS. For example, the bonding layer BL1 of the cell array structure CS may be bonded to the bonding layer BL2 of the peripheral circuit structure PS by a direct bonding method. The bonding pads 173 may be bonded to the bonding pads 43, and the upper insulating layer 170 may be bonded to the lower insulating layer 40. The bonding pads 173 and 43 may include a conductive material such as copper (Cu), and the upper and lower insulating layers 170 and 40 may include an insulating material such as silicon oxide.

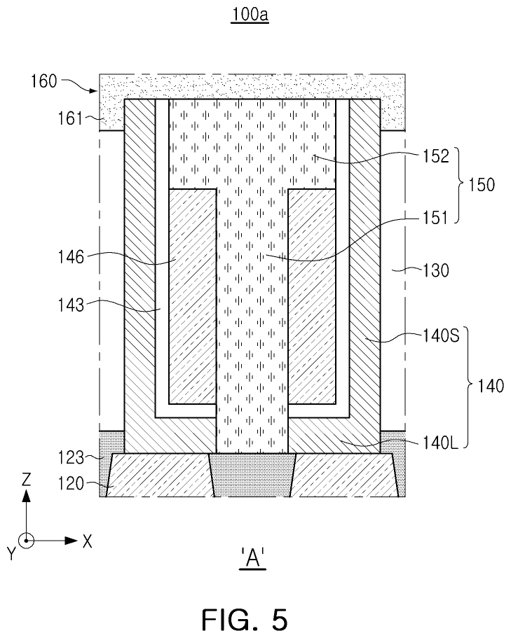

FIGS. 5 to 10 are vertical cross-sectional views of semiconductor devices according to example embodiments. FIGS. 5 to 8 correspond to portion A illustrated in

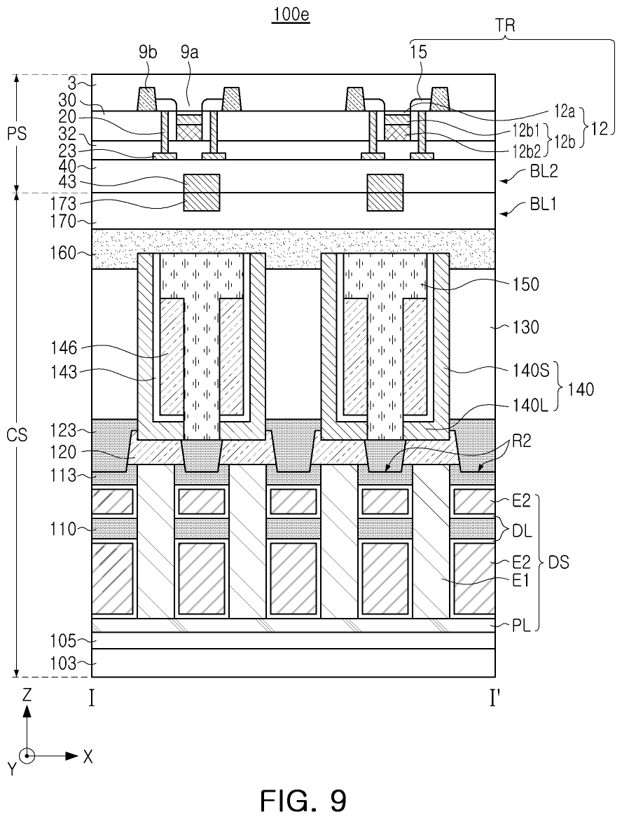

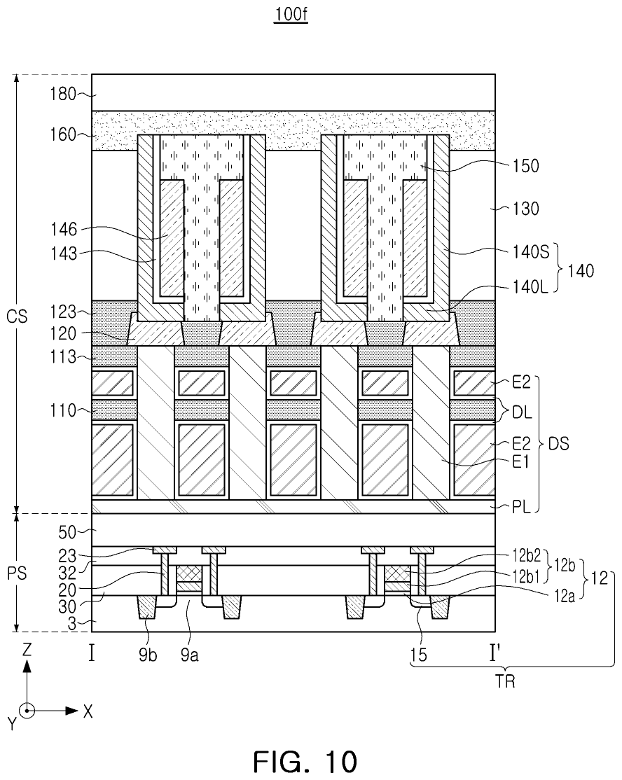

FIG. 2. FIGS. 9 to 10 are vertical cross-sectional views taken along line I-I′ of the semiconductor device illustrated in FIG. 1. Differences are mainly described, and duplicate descriptions are not repeated.

Referring to FIG. 5, a semiconductor device 100a may include a channel structure 140 disposed on a landing pad 120. In an embodiment, a lower surface of a horizontal portion 140L of the channel structure 140 may be in contact with and coplanar with an upper surface of the landing pad 120. For example, a side surface of a vertical channel portion 140S of the channel structure 140 may not be in contact with the landing pad 120.

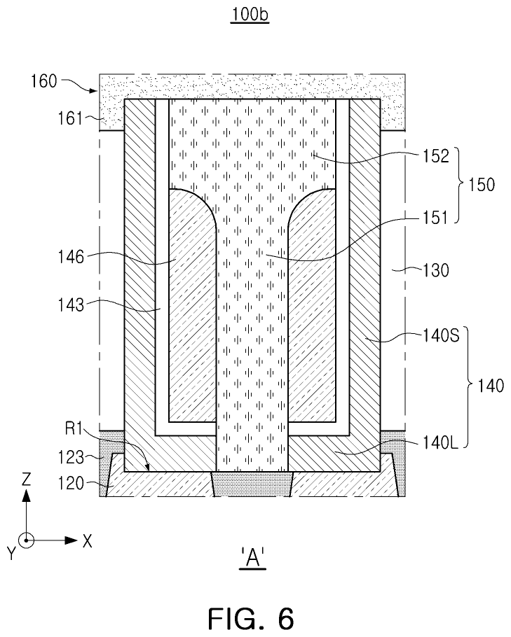

Referring to FIG. 6, a semiconductor device 100b may include a gate electrode 146 disposed on a landing pad 120. In an embodiment, a horizontal width of the gate electrode 146 may become smaller toward a bit line 160. For example, an upper surface of the gate electrode 146 may be rounded. Likewise, a lower surface of the second insulating pattern 150 may be curved to conform to the rounded shape of the upper surface of the gate electrode 146.

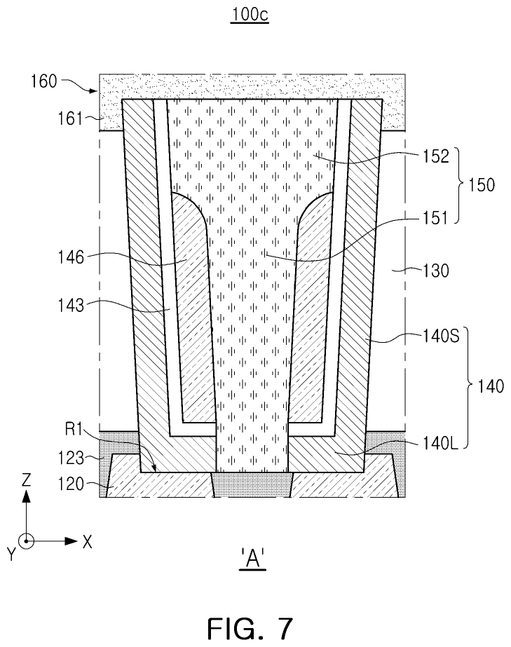

Referring to FIG. 7, a semiconductor device 100c may include a channel structure 140 and a gate electrode 146, arranged on a landing pad 120. In an embodiment, a vertical channel portion 140S of channel structure 140 may extend in the X and Z-directions. The vertical channel portion 140S of channel structure 140 may form an oblique angle with respect to an upper surface of the pad insulating layer 123. For example, a distance between vertical channel portions 140S of adjacent channel structures 140 in the X-direction, with a first insulating pattern 130 therebetween, may decrease in an upward direction (e.g., Z-direction). A distance between the vertical channel portions 140S of the adjacent channel structures 140 in the X-direction, with a second insulating pattern 150 therebetween, may decrease in a downward direction. A horizontal width of the second insulating pattern 150 may decrease in a downward direction. For example, a horizontal width of a lower portion 151 of the second insulating pattern 150 may decrease in a downward direction, and a horizontal width of an upper portion 152 of the second insulating pattern 150 may decrease in a downward direction.

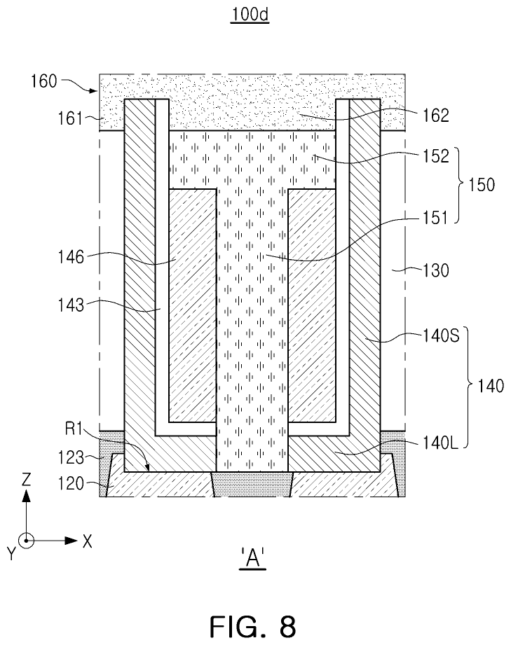

Referring to FIG. 8, a semiconductor device 100d may include a bit line 160 disposed on a channel structure 140. In an embodiment, a portion of a vertical channel portion 140S of channel structure 140 may be buried within the bit line 160. For example, the bit line 160 may include a protrusion 161 extending toward a first insulating pattern 130 in a downward direction, and a protrusion 162 extending toward a second insulating pattern 150 in a downward direction. The protrusion 162 may be in contact with an upper portion 152 of the second insulating pattern 150. A lower end of the protrusion 162 may be located on a level lower than an upper surface of the vertical channel portion 140S. For example, an upper surface of the upper portion 152 of the second insulating pattern 150 may be at a lower vertical level than an upper surface of the channel structure 140. In FIG. 8, a vertical thickness of the protrusion 161 and a vertical thickness of the protrusion 162 are illustrated to be equal to each other, but the present inventive concept is not limited thereto. In some embodiments, the vertical thickness of protrusion 161 may be different from the vertical thickness of protrusion 162.

Referring to FIG. 9, a semiconductor device 100e may include a landing pad 120 and a channel structure 140, arranged on a pad insulating layer 123. In an embodiment, a lower surface of the pad insulating layer 123 may be located on a level lower than a lower surface of the landing pad 120. For example, an upper surface of an upper support layer 113 may include a recess region R2, and the lower surface of the pad insulating layer 123 may extend further from the lower surface of the landing pad 120 in a downward direction, to contact the recess region R2.

Referring to FIG. 10, a semiconductor device 100f may include a cell array structure CS on a peripheral circuit structure PS. For example, an insulating layer 50 may be disposed on a peripheral interconnection 23 of the peripheral circuit structure PS. An information storage structure DS may be disposed on the insulating layer 50. In an embodiment, an insulating layer 180 may be disposed on a bit line 160. Although not illustrated, interconnection layers electrically connected to the bit line 160 may be disposed in the insulating layer 180, and the interconnection layers may be electrically connected to the peripheral circuit structure PS by a through-plug passing through the cell array structure CS.

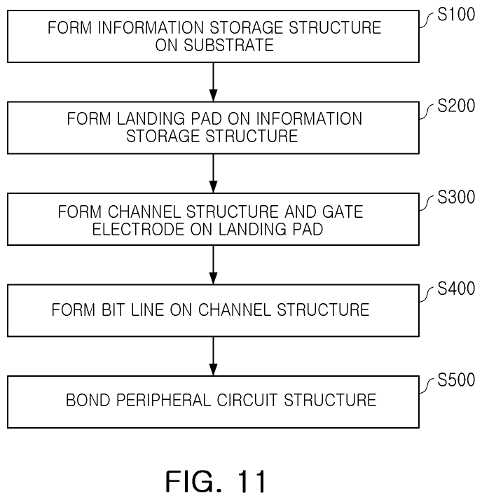

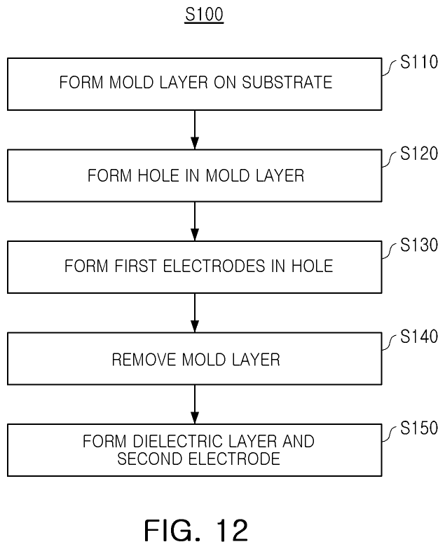

FIGS. 11 and 12 are flow charts illustrating a method of manufacturing a semiconductor device according to an example embodiment.

Referring to FIG. 11, a method of manufacturing a semiconductor device may include forming an information storage structure DS on a substrate 103 (S100) forming a landing pad 120 on the information storage structure DS (S200), forming a channel structure 140 and a gate electrode 146 on the landing pad 120 (S300), forming a bit line 160 on the channel structure 140 (S400), and bonding a peripheral circuit structure thereto (S500).

Referring to FIG. 12, the forming an information storage structure DS on a substrate 103 (S100) may include forming a mold layer on the substrate 103 (S110), forming a hole in the mold layer (S120), forming first electrodes E1 in the hole (S130), removing the mold layer (S140), and forming a dielectric layer DL and a second electrode E2 (S150).

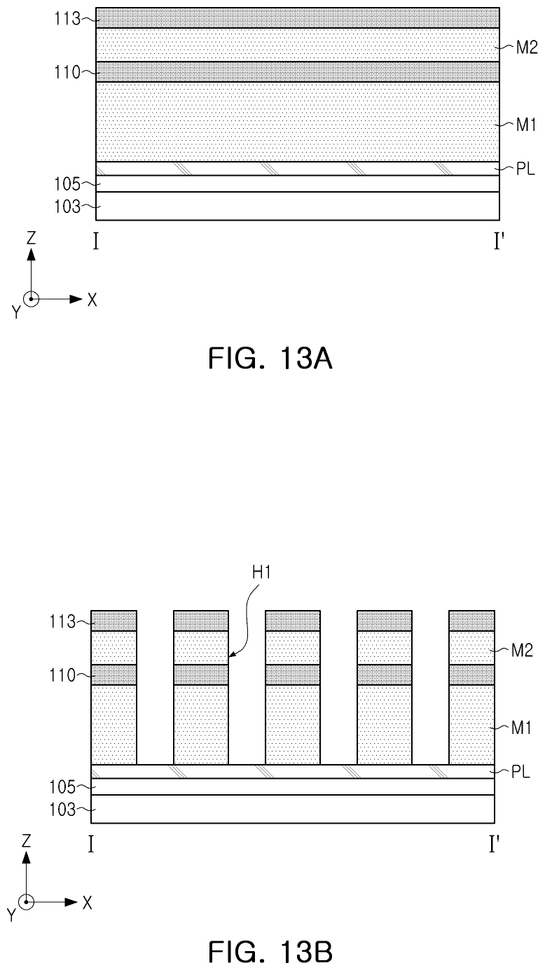

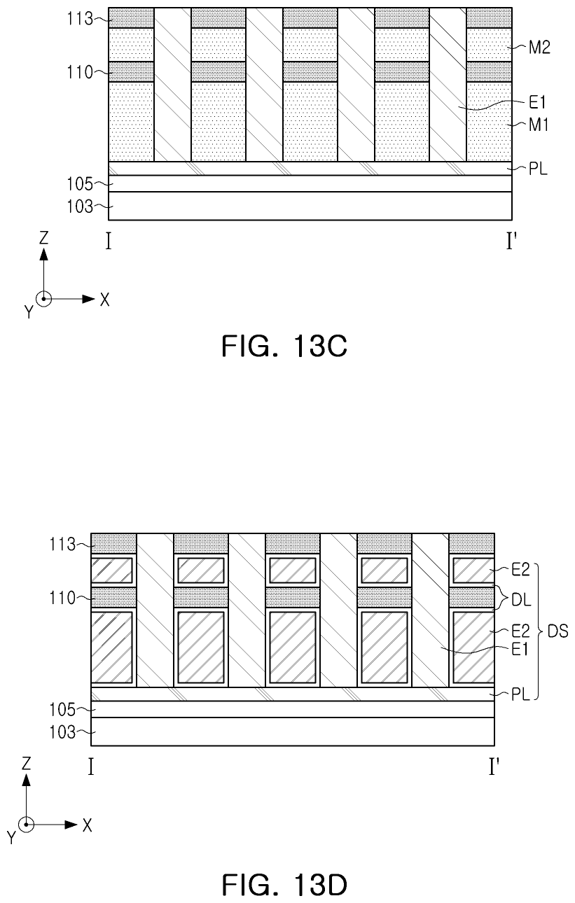

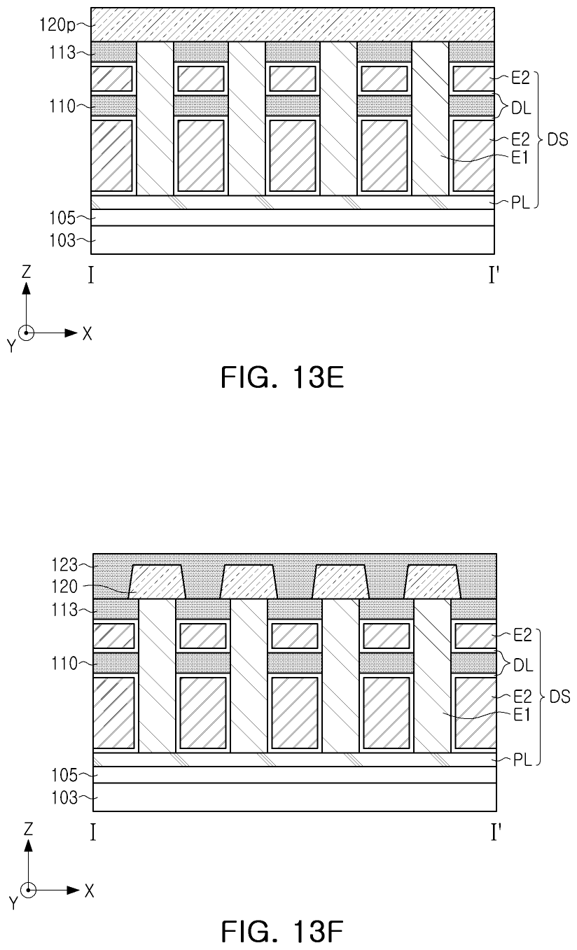

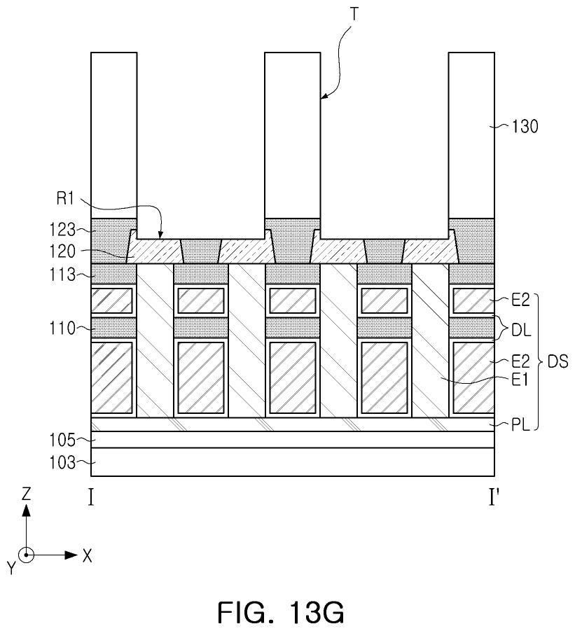

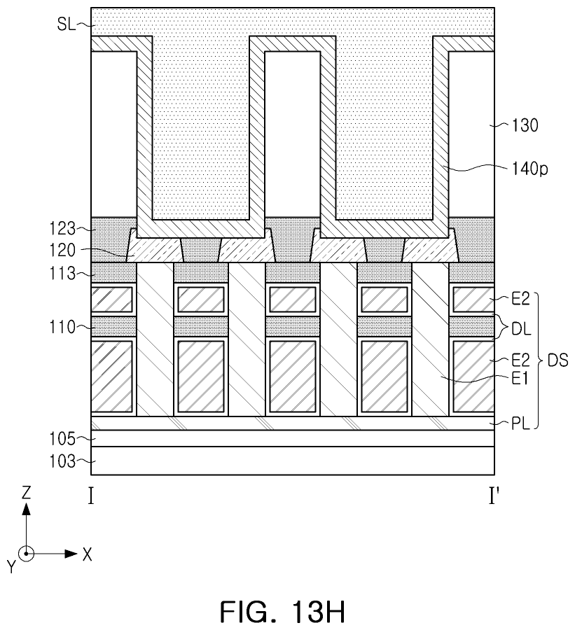

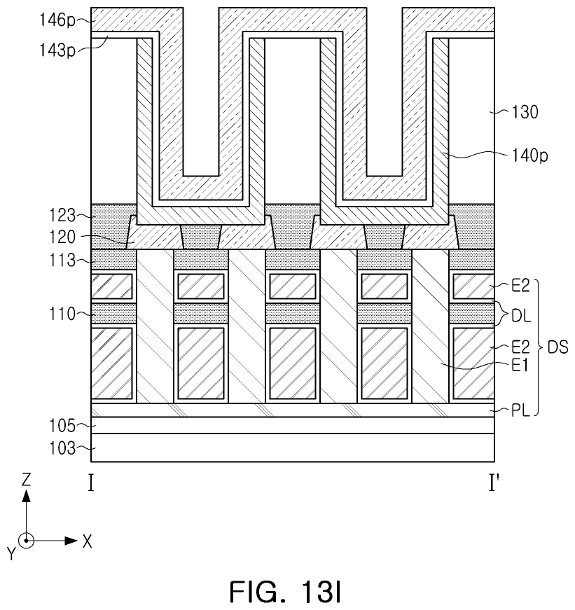

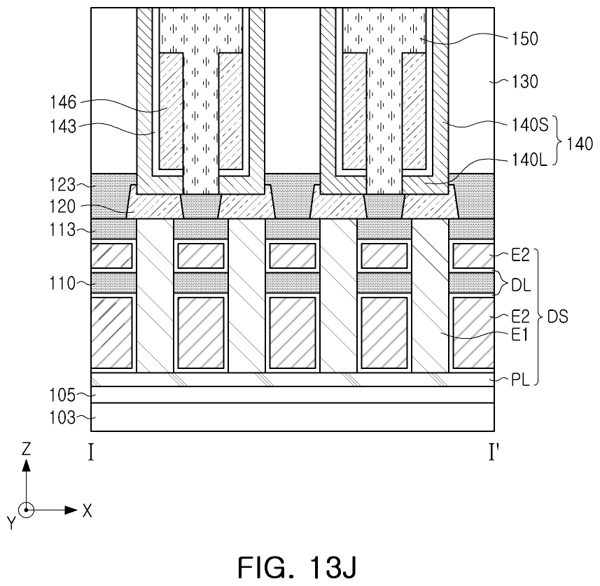

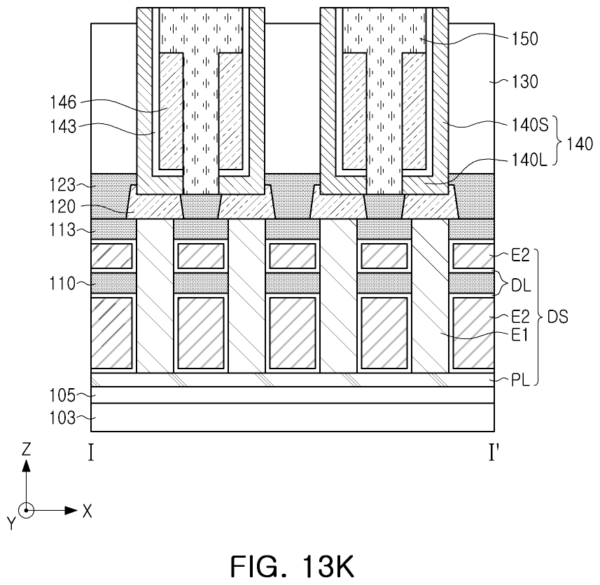

FIGS. 13A to 13K are vertical cross-sectional views illustrated according to a process sequence for illustrating a method of manufacturing a semiconductor device according to an example embodiment. FIGS. 13A to 13K may be vertical cross-sectional views corresponding to FIG. 2.

Referring to FIGS. 11, 12, and 13A, a mold layer may be formed on a substrate 103 (S110). For example, an insulating layer 105, a plate electrode PL, a lower mold layer M1, a lower support layer 110, an upper mold layer M2, and an upper support layer 113 may be sequentially formed on the substrate 103.

The insulating layer 105 may electrically insulate the substrate 103 from the plate electrode PL. The lower mold layer M1 and the upper mold layer M2 may include a material having an etch selectivity with the lower support layer 110 and the upper support layer 113, respectively.

Referring to FIGS. 11, 12, and 13B, a hole H1 may be formed in the mold layers M1 and M2 (S120). The hole H1 may be formed by anisotropically etching the lower mold layer M1, the lower support layer 110, the upper mold layer M2, and the upper support layer 113 to expose the plate electrode PL. The hole H1 may be circular when viewed from the top.

Referring to FIGS. 11, 12, and 13C, first electrodes E1 may be formed in the hole H1 (S130). The first electrodes E1 may be formed by forming a conductive material to fill the hole H1 and planarizing an upper portion of the conductive material to expose the upper support layer 113. Upper surfaces of the first electrodes E1 may be coplanar with an upper surface of the upper support layer 113.

Referring to FIGS. 11, 12, and 13D, the mold layers M1 and M2 may be removed (S140), and a dielectric layer DL and a second electrode E2 may be formed (S150). Since the lower mold layer M1 and the upper mold layer M2 include a material having an etch selectivity with the lower support layer 110 and the upper support layer 113, respectively, the lower support layer 110 and the upper support layer 113 may not be etched, and the lower mold layer M1 and the upper mold layer M2 may be selectively removed.

The dielectric layer DL may be formed conformally along surfaces of the plate electrode PL, the first electrodes E1, the lower support layer 110, and the upper support layer 113. The second electrode E2 may be prepared by forming a conductive material on the dielectric layer DL to fill a space between the first electrodes E1. In an embodiment, when the conductive material covers an upper surface of the upper support layer 113 and upper surfaces of the first electrodes E1, a planarization process may be further performed to expose the upper surface of the upper support layer 113 and the upper surfaces of the first electrodes E1. The plate electrode PL, the first electrodes E1, and the second electrode E2 may form an information storage structure DS.

Referring to FIGS. 11, 13E, and 13F, a landing pad 120 may be formed on the information storage structure DS (S200). A conductive layer 120p covering the upper surface of the upper support layer 113 and the upper surfaces of the first electrodes E1 may be formed. The landing pad 120 may be prepared by forming a mask layer on the conductive layer 120p and performing an anisotropic etching process using the mask layer as an etch mask. Landing pads 120 may respectively be disposed on a first electrode E1 corresponding thereto. After the landing pad 120 is formed, a pad insulating layer 123 covering the landing pad 120 may be formed. An upper surface of the pad insulating layer 123 may be located on a level higher than upper surfaces of the landing pads 120.

In an embodiment, as illustrated in FIG. 9, the upper support layer 113 may be partially etched by the anisotropic etching process, to forming a recess region R2 on an upper surface of the upper support layer 113.

Referring to FIGS. 11 and 13G to 13J, a channel structure 140 and a gate electrode 146 may be formed on the landing pad 120 (S300). First insulating patterns 130 may be formed by depositing an insulating material on the pad insulating layer 123 and performing an anisotropic etching process to expose the landing pad 120. The insulating material and the pad insulating layer 123 may be etched by the anisotropic etching process to form a trench T extending in the Y-direction. The trench T may expose side surfaces of the first insulating patterns 130, and may expose the upper surface of the landing pad 120. In an embodiment, a portion of the landing pad 120 may be etched by the anisotropic etching process to form a recess region R1 on the upper surface of the landing pad 120.

In an embodiment, as illustrated in FIG. 5, the landing pad 120 may not be etched by the anisotropic etching process, and the recess region R1 may not be formed on the upper surface of the landing pad 120.

A channel material layer 140p conformally covering the trenches T and a sacrificial layer SL on the channel material layer 140p may be formed. The channel material layer 140p may be in contact with the upper surface of the landing pad 120, and the sacrificial layer SL may fill the trench T.

A portion of the channel material layer 140p covering the upper surfaces of the first insulating patterns 130 may be removed by a planarization process. After the planarization process, the channel material layer 140p may be disposed along an internal wall of the trench T, and upper surfaces of the first insulating patterns 130 may be exposed.

A dielectric material layer 143p may be formed conformally along the first insulating patterns 130 and the channel material layer 140p. A conductive layer 146p may be conformally formed on the dielectric material layer 143p.

An anisotropic etching process may be performed to expose an upper surface of the pad insulating layer 123, and the channel material layer 140p, the dielectric material layer 143p, and the conductive layer 146p may be partially removed to form a channel structure 140, a dielectric structure 143, and a gate electrode 146. The channel structures 140, the dielectric structures 143, and the gate electrodes 146 may be disposed on landing pads 120 respectively corresponding thereto.

In an embodiment, as illustrated in FIGS. 6 and 7, a horizontal width of the gate electrode 146 may decrease in an upward direction.

After the gate electrodes 146 are formed, a second insulating pattern 150 covering the gate electrode 146 may be formed. An upper surface of the second insulating pattern 150 may be coplanar with an upper surface of the channel structure 140.

Referring to FIG. 13K, the first insulating pattern 130 may be partially etched to expose a side surface of the channel structure 140. For example, an isotropic etching process may be performed to remove an upper portion of the first insulating pattern 130. After the etching process is performed, the upper surface of the first insulating pattern 130 may be located on a level lower than the upper surface of the channel structure 140.

In an embodiment, as illustrated in FIG. 8, a portion of the second insulating pattern 150 may be removed by the isotropic etching process. For example, an upper surface of the second insulating pattern 150 may be located on a level lower than the upper surface of the channel structure 140.

After the upper portion of the first insulating pattern 130 is removed, a heating process may be performed. The channel structure 140 may be heated by the heating process, and oxygen atoms may move from the first insulating pattern 130 including silicon oxide to the channel structure 140. Therefore, oxygen vacancies in the channel structure 140 including an oxide semiconductor layer may be reduced, and a cell active leakage current (Ioff) may be reduced and prevented. For example, when a cell transistor is not in operation, the cell active leakage current may be reduced, and when a voltage is applied to the gate electrode 146 and the cell transistor is in operation, current may flow in the channel structure 140, such that the semiconductor device 100 Switching characteristics may be improved.

Referring again to FIGS. 1 to 3, a bit line 160 may be formed on the channel structure 140 (S400). The bit line 160 may cover the first insulating pattern 130 and the channel structure 140, and may extend in the X-direction. Since the upper surface of the first insulating pattern 130 may be located on a level lower than the upper surface of the channel structure 140, a portion of the bit line 160 formed on the first insulating pattern 130 and the channel structure 140 may protrude toward the first insulating pattern 130. A bonding layer BL1 including an upper insulating layer 170 and a bonding pad 173 may be formed on the bit line 160. Components from the substrate 103 to the bonding layer BL1 may form a cell array structure CS.

The peripheral circuit structure PS may be bonded to the cell array structure CS (S500), and the semiconductor device 100 may be manufactured. For example, the peripheral circuit structure PS may include a bonding layer BL2 including a lower insulating layer 40 and a bonding pad 43, and the bonding layer BL2 may be bonded to the bonding layer BL1.

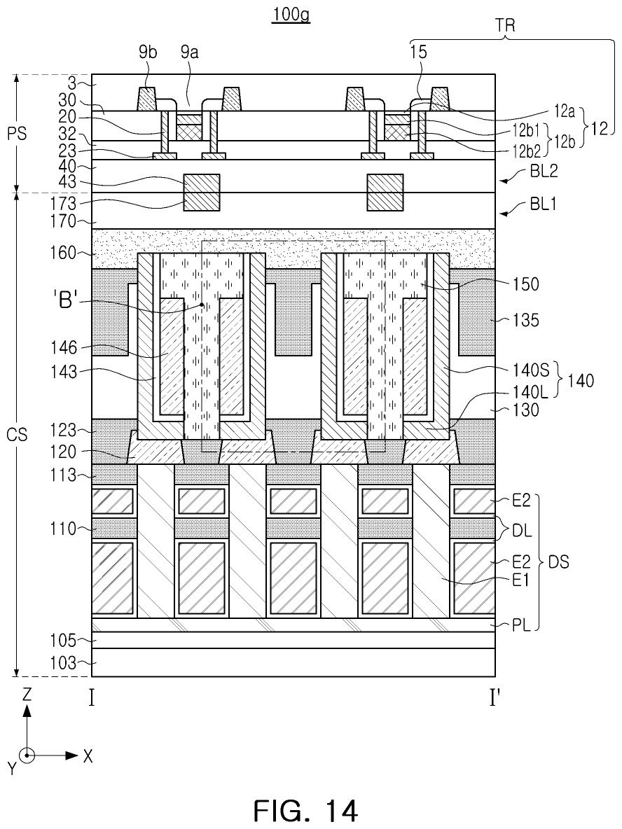

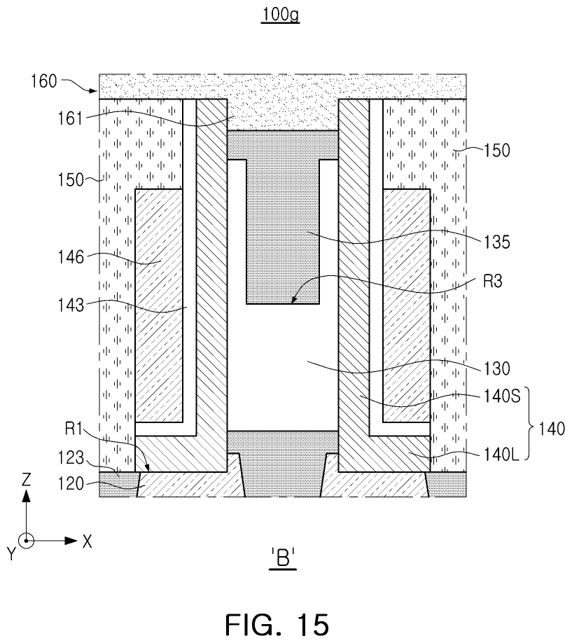

FIG. 14 is a vertical cross-sectional view of a semiconductor device according to an example embodiment. FIG. 15 is a partially enlarged view of the semiconductor device illustrated in FIG. 14. FIG. 15 corresponds to portion B illustrated in FIG. 14. Differences are mainly described, and duplicate descriptions are not repeated.

Referring to FIGS. 14 and 15, a semiconductor device 100g may include a filling layer 135 disposed on a first insulating pattern 130. For example, the first insulating pattern 130 may include a recess region R3 formed on an upper surface of the first insulating pattern 130. The filling layer 135 may fill the recess region R3. The filling layer 135 may contact the first insulating pattern 130 and a side surface of the vertical channel portion 140S of the channel structure 140. An upper surface of the filling layer 135 may be located on a level lower than an upper surface of the vertical channel portion 140S of the channel structure 140. A protrusion 161 of the bit line 160 may be in contact with the filling layer 135.

In an embodiment, the filling layer 135 may be formed of or include a material, different from a material of the first insulating pattern 130. For example, the first insulating pattern 130 may be formed of or include silicon oxide, and the filling layer 135 may include silicon nitride.

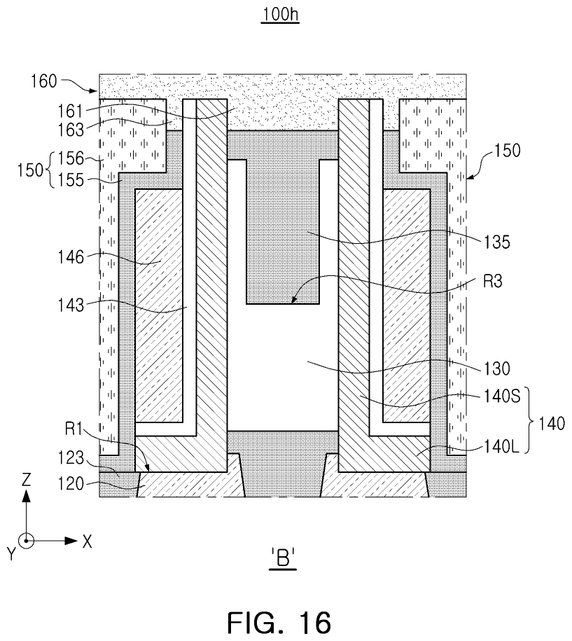

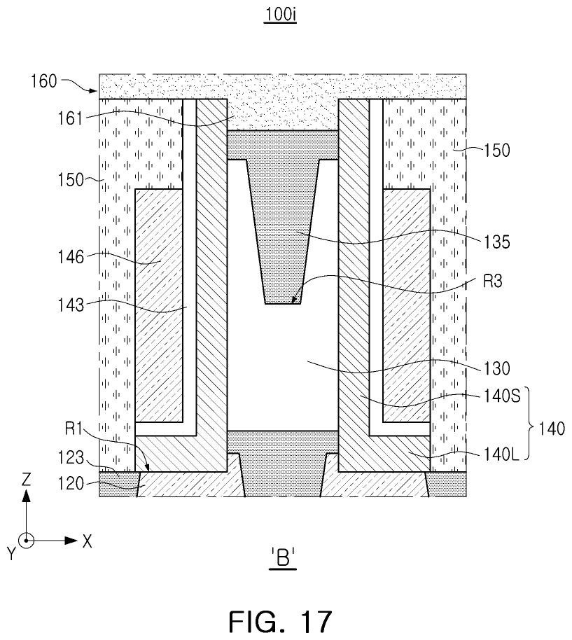

FIGS. 16 and 17 are partially enlarged views of the semiconductor device illustrated in FIG. 14. FIGS. 16 and 17 correspond to portion B illustrated in FIG. 14. Differences are mainly described, and duplicate descriptions are not repeated.

Referring to FIG. 16, a semiconductor device 100h may include a second insulating pattern 150 covering a gate electrode 146. In an embodiment, the second insulating pattern 150 may include a first material layer 155 and a second material layer 156 on the first material layer 155. The first material layer 155 may cover a dielectric structure 143, a gate electrode 146, and a pad insulating layer 123. The second material layer 156 may fill a space between gate electrodes 146.

In an embodiment, the first material layer 155 may be formed of or include a material, different from a material of the second material layer 156. For example, the first material layer 155 may be formed of or include silicon nitride, and the second material layer 156 may be formed of or include silicon oxide.

In an embodiment, an upper end of the first material layer 155 may be located on a level lower than an upper surface of a vertical channel portion 140S of a channel structure 140. For example, a bit line 160 may include a protrusion 163 extending from a lower surface of the bit line 160 in a downward direction. The protrusion 163 may be in contact with a side surface of the second material layer 156 and a side surface of the dielectric structure 143. A lower end of the protrusion 163 may be located on a level lower than an upper surface of the second material layer 156 and the upper surface of the vertical channel portion 140S.

Referring to FIG. 17, a semiconductor device 100i may include a filling layer 135 disposed on a first insulating pattern 130. In an embodiment, the horizontal width of the filling layer 135 may decrease in a downward direction. For example, a horizontal width of the filling layer 135 may decrease toward a landing pad 120, and may increase toward a bit line 160.

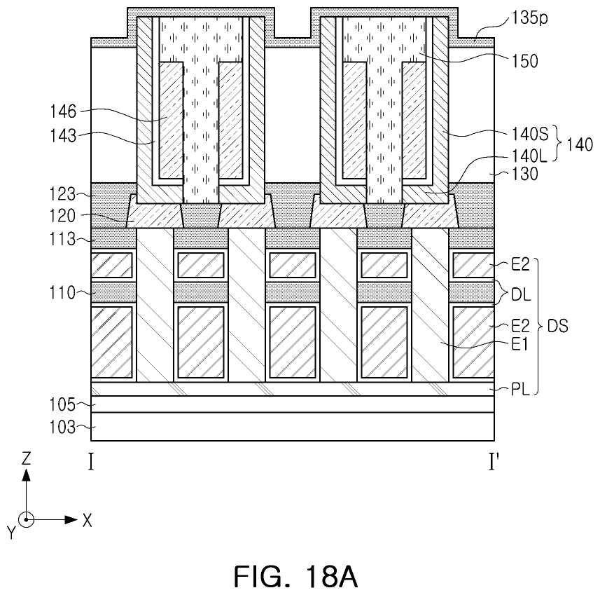

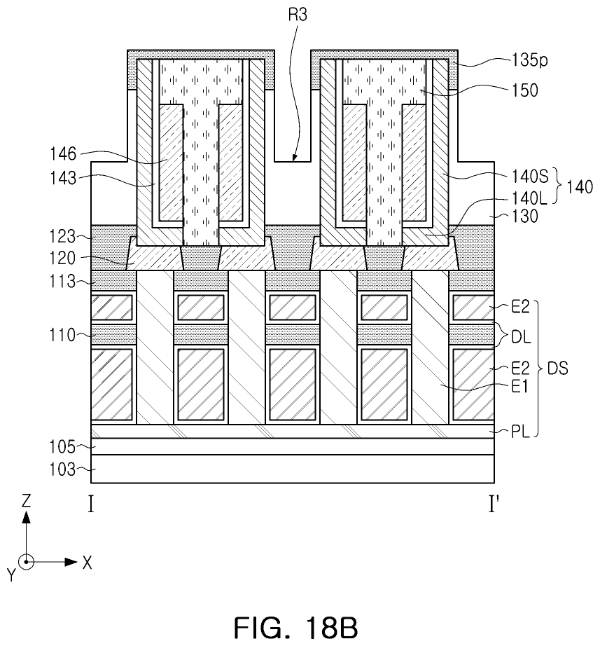

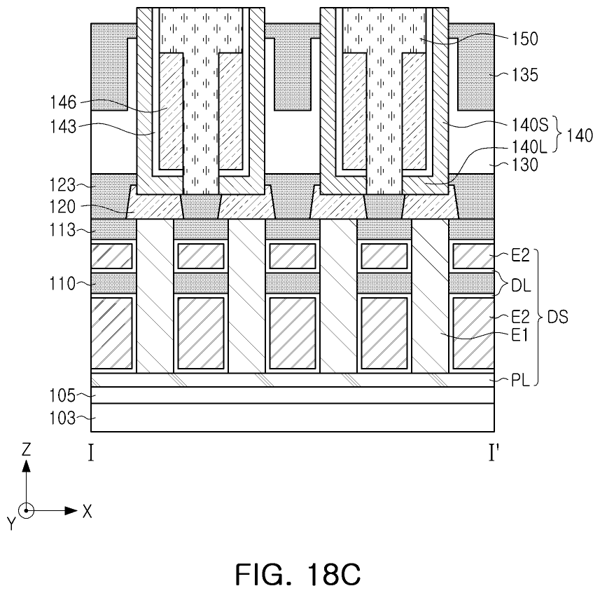

FIGS. 18A to 18C are vertical cross-sectional views illustrated according to a process sequence for illustrating a method of manufacturing a semiconductor device according to an example embodiment.

Referring to FIG. 18A, after an etching process of a first insulating pattern 130, as described with reference to FIG. 13K, a protective layer 135p may be formed. The protective layer 135p may cover first insulating patterns 130, channel structures 140, dielectric structures 143, and second insulating patterns 150.

Referring to FIG. 18B, an anisotropic etching process may be performed to partially etch the protective layer 135p and the first insulating patterns 130. For example, recess regions R3 may be formed on upper surfaces of the first insulating patterns 130, and side surfaces of the first insulating patterns 130 may be exposed. During the anisotropic etching process, the protective layer 135p may protect the channel structures 140 from etching thereof.

After the side surfaces of the first insulating patterns 130 are exposed, a heating process may be performed. The channel structure 140 may be heated by the heating process, and oxygen atoms may move from the first insulating pattern 130 including silicon oxide to the channel structure 140. Therefore, oxygen vacancies in the channel structure 140 including an oxide semiconductor layer may be reduced, and a cell active leakage current (Ioff) may be reduced and prevented. As illustrated in FIG. 18B, since the heating process may be performed after the side surfaces of the first insulating patterns 130 are exposed, oxygen vacancies in the channel structure 140 may be more effectively reduced.

Referring to FIG. 18C, a filling layer 135 may be formed on the first insulating pattern 130. The filling layer 135 may be formed with an insulating material to cover the recess region R3, the channel structures 140, and the second insulating patterns 150, and an anisotropic etching process may then be performed to expose the channel structures 140. The insulating material may be etched by the isotropic etching process, and an upper surface of the filling layer 135 may be located on a level lower than an upper surface of a vertical channel portion 140S of the channel structure 140.

Thereafter, a cell array structure CS may be prepared by forming a bit line 160 and a bonding layer BL1. A semiconductor device 100g may be manufactured by bonding a peripheral circuit structure PS onto the cell array structure CS.

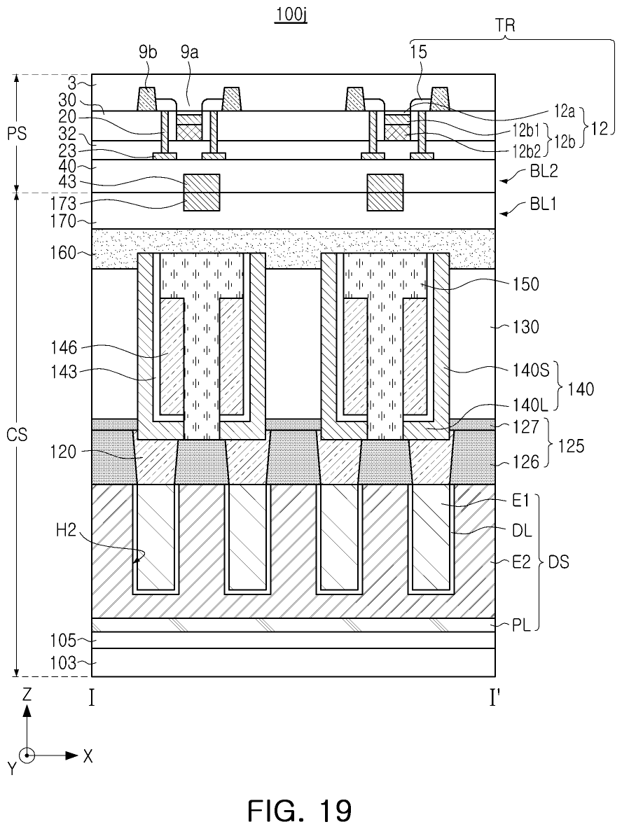

FIG. 19 is a vertical cross-sectional view of a semiconductor device according to an example embodiment. FIG. 19 is a vertical cross-sectional view taken along line I-I′ of the semiconductor device illustrated in FIG. 1. Differences are mainly described, and duplicate descriptions are not repeated.

Referring to FIG. 19, a semiconductor device 100j may include an information storage structure DS disposed below a channel structure 140. The information storage structure DS may include a plate electrode PL, first electrodes E1, a second electrode E2 on the first electrodes E1, and a dielectric layer DL between each of the first electrodes E1 and the second electrode E2. In an embodiment, the second electrode E2 may include holes H2 on an upper surface of the second electrode E2, and the first electrodes E1 may be disposed in the holes H2. For example, the dielectric layers DL may be conformally disposed along an internal wall of each of the holes H2, and the first electrodes E1 may be disposed on the dielectric layers DL, and may fill the holes H2. Lower surfaces of the first electrodes E1 may be located on a level higher than lower surfaces of the second electrodes E2. Upper surfaces of the first electrodes E1 may be coplanar with upper ends of the dielectric layers DL and upper surfaces of the second electrode E2.

The semiconductor device 100j may include a landing pad 120 and a pad insulating layer 125 covering the landing pads 120. Each of the landing pads 120 may be in contact with an upper surface of a first electrode E1 corresponding thereto, and may be electrically connected. In an embodiment, a horizontal width of a lower surface of the landing pad 120 may be less than or equal to a horizontal width of the upper surface of the first electrode E1. In an embodiment, a horizontal width of the landing pad 120 may become smaller in a downward direction. For example, the horizontal width of the landing pad 120 may become smaller toward the information storage structure DS, and may become larger toward the channel structure 140.

The pad insulating layer 125 may include a first pad insulating layer 126 and a second pad insulating layer 127 on the first pad insulating layer 126. The first pad insulating layer 126 may be disposed on the same level as the landing pads 120, and may cover side surfaces of the landing pads 120. For example, lower and upper surfaces of the first pad insulating layer 126 may be coplanar with lower and upper surfaces of the landing pads 120, respectively. The first pad insulating layer 126 may contact side surfaces of the landing pads 120. The lower surface of the first pad insulating layer 126 may be in contact with the upper surface of the second electrode E2.

The second pad insulating layer 127 may be disposed on the first pad insulating layer 126 and the landing pads 120. The second pad insulating layer 127 may contact upper surfaces of the first pad insulating layer 126 and the landing pads 120. The second pad insulating layer 127 may be in contact with a side surface of a vertical channel portion 140S. The first pad insulating layer 126 and the second pad insulating layer 127 may include silicon oxide, silicon nitride, silicon oxynitride, a low-κ dielectric, or a combination thereof, and may include, for example, silicon nitride.

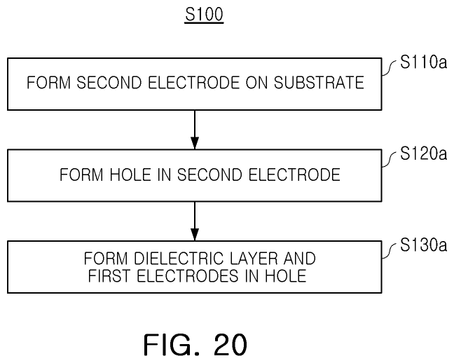

FIG. 20 is a flow chart illustrating a method of manufacturing a semiconductor device according to an example embodiment.

Referring to FIG. 20, the forming an information storage structure DS on a substrate 103 (S100) may include forming a second electrode E2 on the substrate 103 (S110a), forming a hole H2 in the electrode E2 (S120a), and forming a dielectric layer DL and a first electrode E1 in the hole H2 (S130a).

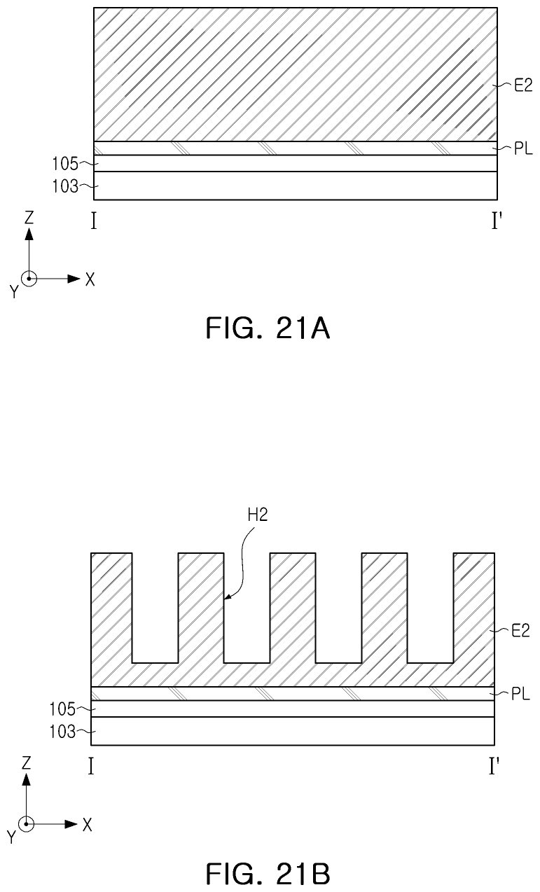

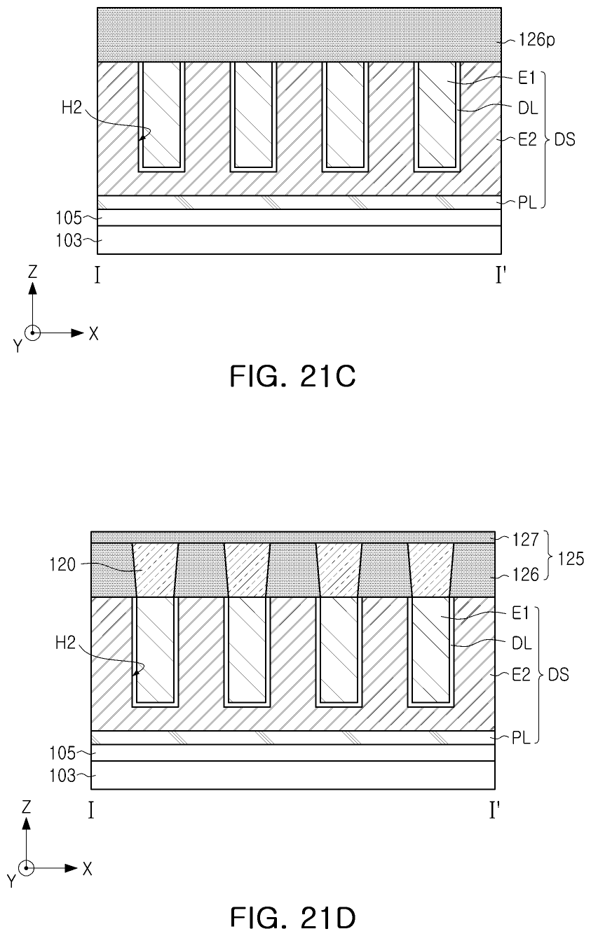

FIGS. 21A to 21D are vertical cross-sectional views illustrated according to a process sequence for illustrating a method of manufacturing a semiconductor device according to an example embodiment.

Referring to FIGS. 20 and 21A, a second electrode E2 may be formed on a substrate 103 (S110a). For example, an insulating layer 105, a plate electrode PL, and the second electrode E2 may be sequentially formed on the substrate 103.

Referring to FIGS. 20 and 21B, holes H2 may be formed in the second electrode E2 (S120a). The holes H2 may be formed by anisotropically etching the second electrode E2, and a depth of the holes H2 may be smaller than a height of the second electrode E2. For example, an upper surface of the plate electrode PL may not be exposed.

Referring to FIGS. 20 and 21C, a dielectric layer DL and a first electrode E1 may be formed in each of the holes H2 (S130a). The dielectric layer DL may be formed conformally along an internal wall of the hole H2 and an upper surface of the second electrode E2. The first electrodes E1 may be prepared by forming a conductive material to fill the holes H2 and performing a planarization process to expose the upper surface of the second electrode E2. The upper surface of the second electrode E2 may not be covered by the dielectric layer DL and the first electrodes E1.

After the dielectric layer DL and the first electrodes E1 are formed, an insulating material layer 126p may be formed on the dielectric layer DL, the first electrodes E1, and the second electrode E2.

Referring to FIG. 21D, holes may be formed by patterning the insulating material layer 126p such that upper surfaces of the first electrodes E1 are exposed. Landing pads 120 may be formed by filling the hole with a conductive material. The patterned insulating material layer 126p may be referred to as a first pad insulating layer 126. After the landing pads 120 are formed, a second pad insulating layer 127 covering the landing pads 120 and the first pad insulating layer 126 may be formed. The first pad insulating layer 126 and the second pad insulating layer 127 may form a pad insulating layer 125.

Thereafter, a method of forming a cell array structure CS and a peripheral circuit structure PS, as described with reference to FIGS. 1 to 3 and FIGS. 13G to 13K, may be performed to manufacture a semiconductor device 100j.

According to embodiments of the technical idea of the present inventive concept, a channel structure may be disposed on an information storage structure. Lower and side surfaces of the channel structure may be in contact with a landing pad, and upper and side surfaces of the channel structure may be in contact with a bit line. A contact area between the landing pad and the bit line and a contact area between the landing pad and the channel structure may increase, and a contact resistance therebetween may decrease. Therefore, electrical characteristics of a semiconductor device may be improved.

Various advantages and effects of the present inventive concept are not limited to the above-described content, and can be more easily understood through description of specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
an information storage structure on a substrate;
a landing pad on the information storage structure;
a channel structure including a horizontal portion contacting an upper surface of the landing pad, and a vertical channel portion extending from one end of the horizontal portion in an upward direction;
a gate electrode disposed on the horizontal portion; and
a bit line contacting an upper surface of the vertical channel portion and electrically connected to the channel structure,
wherein a lower surface of the horizontal portion is located on a lower level than an upper end of the landing pad, and
wherein a side surface of the vertical channel portion is partially in contact with the landing pad.

2. The semiconductor device of claim 1, further comprising:
a first insulating pattern disposed on the landing pad and contacting the vertical channel portion of the channel structure; and
a second insulating pattern disposed on the landing pad and covering the gate electrode.

3. The semiconductor device of claim 2,
wherein the bit line further comprises a first protrusion extending from a lower surface of the bit line in a downward direction and contacting an upper surface of the first insulating pattern, and
wherein a lower end of the first protrusion is located on a lower level than the upper surface of the vertical channel portion of the channel structure.

4. The semiconductor device of claim 3,
wherein the bit line further comprises a second protrusion extending from the lower surface of the bit line in the downward direction and contacting an upper surface of the second insulating pattern, and
wherein a lower end of the second protrusion is located on a lower level than the upper surface of the vertical channel portion of the channel structure.

5. The semiconductor device of claim 3,
wherein the second insulating pattern comprises a first material layer contacting the gate electrode, and a second material layer on the first material layer,
wherein the bit line further comprises a second protrusion extending from the lower surface of the bit line in the downward direction and contacting an upper surface of the second insulating pattern and a side surface of the second material layer, and
wherein a lower end of the second protrusion is located on a lower level than the upper surface of the vertical channel portion of the channel structure.

6. The semiconductor device of claim 2, wherein a horizontal width of the second insulating pattern decreases toward the landing pad.

7. The semiconductor device of claim 2,
wherein the first insulating pattern comprises a recess region on an upper surface of the first insulating pattern, and
wherein the semiconductor device further comprises a filling layer filling the recess region of the first insulating pattern.

8. The semiconductor device of claim 7, wherein a horizontal width of the filling layer decreases toward the landing pad.

9. The semiconductor device of claim 1, wherein a horizontal width of the gate electrode decreases toward the bit line.

10. The semiconductor device of claim 1, further comprising a pad insulating layer covering side and upper surfaces of the landing pad.

11. The semiconductor device of claim 10, wherein an upper surface of the pad insulating layer is located on a higher level than the lower surface of the horizontal portion of the channel structure.

12. The semiconductor device of claim 10, wherein a lower surface of the pad insulating layer is located on a lower level than a lower surface of the landing pad.

13. A semiconductor device comprising:
a cell array structure; and
a peripheral circuit structure vertically overlapping the cell array structure and including a circuit element,
wherein the cell array structure includes:
an information storage structure;
a landing pad on the information storage structure;
a channel structure including a horizontal portion contacting an upper surface of the landing pad, and a vertical channel portion extending from one end of the horizontal portion in an upward direction;
a gate electrode disposed on the horizontal portion;
a first insulating pattern contacting the vertical channel portion;
a second insulating pattern covering the gate electrode; and
a bit line contacting an upper surface of the vertical channel portion and electrically connected to the channel structure,
wherein the upper surface of the vertical channel portion is disposed on a higher level than an upper surface of the first insulating pattern, and
wherein a lower surface of the horizontal portion is disposed on a lower level than a lower surface of the first insulating pattern.

14. The semiconductor device of claim 13,
wherein the bit line comprises a protrusion extending from a lower surface of the bit line in a downward direction, and
wherein a lower end of the protrusion is located on a lower level than the upper surface of the vertical channel portion.

15. The semiconductor device of claim 13,
wherein the channel structure comprises a first channel structure and a second channel structure, spaced apart from each other, with the second insulating pattern therebetween, and
wherein a distance between the first channel structure and the second channel structure on a first vertical level equal to a lower surface of the bit line is greater than a distance between the first channel structure and the second channel structure on a second vertical level equal to the upper surface of the landing pad.

16. The semiconductor device of claim 15, wherein a distance between a vertical channel portion of the first channel structure and a vertical channel portion of the second channel structure decreases toward the landing pad.

17. The semiconductor device of claim 13,
wherein the information storage structure comprises first electrodes, a second electrode on the first electrodes, and a dielectric layer between each of the first electrodes and the second electrode,
wherein the cell array structure further comprises an upper support layer contacting side surfaces of the first electrodes, and
wherein upper surfaces of the first electrodes are coplanar with the upper support layer.

18. The semiconductor device of claim 17,
wherein a horizontal width of the landing pad decreases toward the channel structure, and
wherein a horizontal width of a lower surface of the landing pad is greater than a horizontal width of an upper surface of at least one of the first electrodes.

19. The semiconductor device of claim 13,
wherein the information storage structure comprises first electrodes, a second electrode on the first electrodes, and a dielectric layer between each of the first electrodes and the second electrode, and
wherein upper surfaces of the first electrodes are coplanar with an upper surface of the second electrode.

20. A semiconductor device comprising:
an information storage structure on a substrate;
a landing pad on the information storage structure;
a channel structure including a horizontal portion contacting an upper surface of the landing pad, and a vertical channel portion extending from one end of the horizontal portion in an upward direction;
a gate electrode disposed on the horizontal portion;
a dielectric structure between the channel structure and the gate electrode;
a first insulating pattern contacting the vertical channel portion;
a second insulating pattern covering the gate electrode and the dielectric structure;
a bit line contacting an upper surface of the vertical channel portion and electrically connected to the channel structure;
a first bonding layer on the bit line; and
a peripheral circuit structure including a second bonding layer bonded to the first bonding layer and a circuit element on the second bonding layer,
wherein a side surface of a lower portion of the vertical channel portion is in contact with the landing pad, and a side surface of an upper portion of the vertical channel portion is in contact with the bit line.
